(19) United States
(12) Patent Application Publication
(10) Pub. No.: US 2026/0353680 A1
(43) Pub. Date: Nov. 5, 2026

(54) SEMICONDUCTOR DEVICE WITH INDUCTIVE COMPONENT AND METHOD OF FORMING

(71) Applicant: Taiwan Semiconductor Manufacturing Co., Ltd., Hsinchu (TW)

(72) Inventors: Szu-Shu Yang, Tainan City (TW); Chun Yi Wu, Tainan City (TW); Kai Tzeng, Neipu Township (TW); Yuh-Sen Chang, Chupei City (TW); Chi-Cheng Chen, Tainan City (TW); Chi-Chun Peng, Hsinchu (TW)

(21) Appl. No.: 19/742,824

(22) Filed: Jul. 15, 2026

Related U.S. Application Data
(62) Division of application No. 18/150,912, filed on Jan. 6, 2023.

(51) Int. Cl. H10D 1/20; H10D 1/00

(52) U.S. Cl. CPC H10D 1/20; H10D 1/01

(57) ABSTRACT

A method of forming a semiconductor device, the method including forming a first insulation layer over a substrate, depositing a first stack of magnetic layers over the first insulation layer, etching the first stack of magnetic layers such that a sidewall of the first stack of magnetic layers forms a stairstep pattern, forming a first photosensitive layer over the first stack of magnetic layers, the first insulation layer, and the substrate, wherein a thickness of the first photosensitive layer above a center of a first step of the stairstep pattern is different from a thickness of the first photosensitive layer above a center of a second step of the stairstep pattern, forming a first conductive feature over the first photosensitive layer, depositing a second insulation layer over the first photosensitive layer and the first conductive feature, and depositing a second magnetic layer over the second insulation layer.

### CROSS-REFERENCE TO RELATED APPLICATIONS

This application is a divisional application of U.S. Patent Application No. 18/150,912, filed on Jan. 6, 2023, which application is hereby incorporated herein by reference.

### BACKGROUND

Semiconductor devices are used in a variety of electronic applications, such as personal computers, cell phones, digital cameras, and other electronic equipment, as examples. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the integration density increases, challenges arise in the manufacturing of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 12B illustrate various views of a semiconductor device at various stages of manufacturing, in accordance with an embodiment.

FIG. 13 illustrates a cross-sectional view of a semiconductor structure, in accordance with an embodiment.

FIG. 14 illustrates traces of saturation current versus inductance for example inductors.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the description herein, unless otherwise specified, the same or similar reference numerals in different figures refer to the same or similar element formed by a same or similar formation method using a same or similar material(s).

Various embodiments provide methods applied to the forming of an inductive component over a passivation layer of a semiconductor die. Forming the inductive component includes forming a first magnetic film over the passivation layer and performing an etching process to cause a sidewall of the first magnetic film to have a stairstep pattern. A first polymer layer is then formed over the first magnetic film, such that a first portion of the first polymer layer that overlaps the stairstep pattern has a sloping top surface. In addition, a thickness of the first polymer layer above a center point of a top surface of each step of the stairstep pattern increases in a direction from a topmost step of the stairstep pattern towards a bottommost step of the stairstep pattern. A second polymer layer is formed over the first polymer layer. A first insulation layer is then formed over the second polymer layer and the first polymer layer. Advantageous features of one or more embodiments disclosed herein may allow for better adhesion between the first insulation layer and the first polymer layer, which results in a reduced risk of delamination and cracking of the first insulation layer that overlaps the stairstep pattern of the first magnetic film. In addition, one or more embodiments disclosed herein may allow for induction devices having improved electrical properties that are able to achieve higher inductance values.

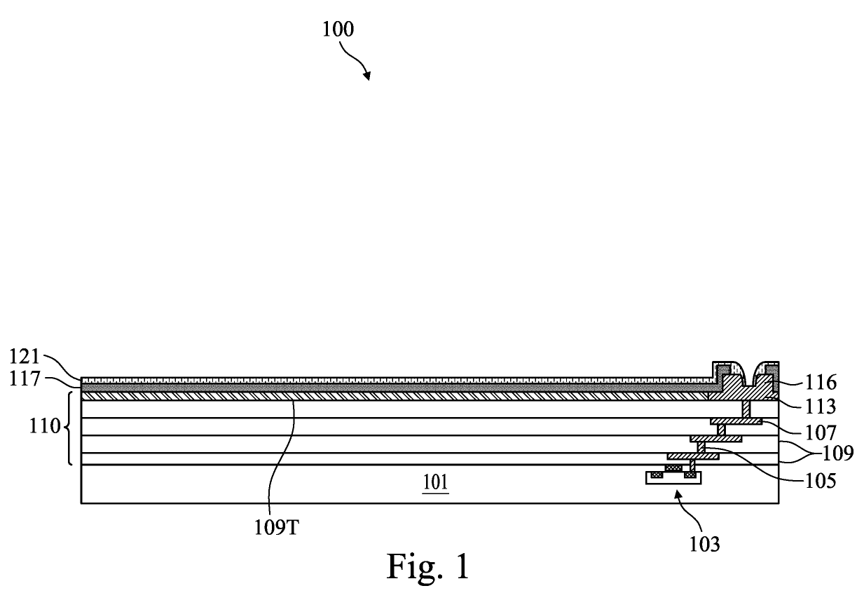

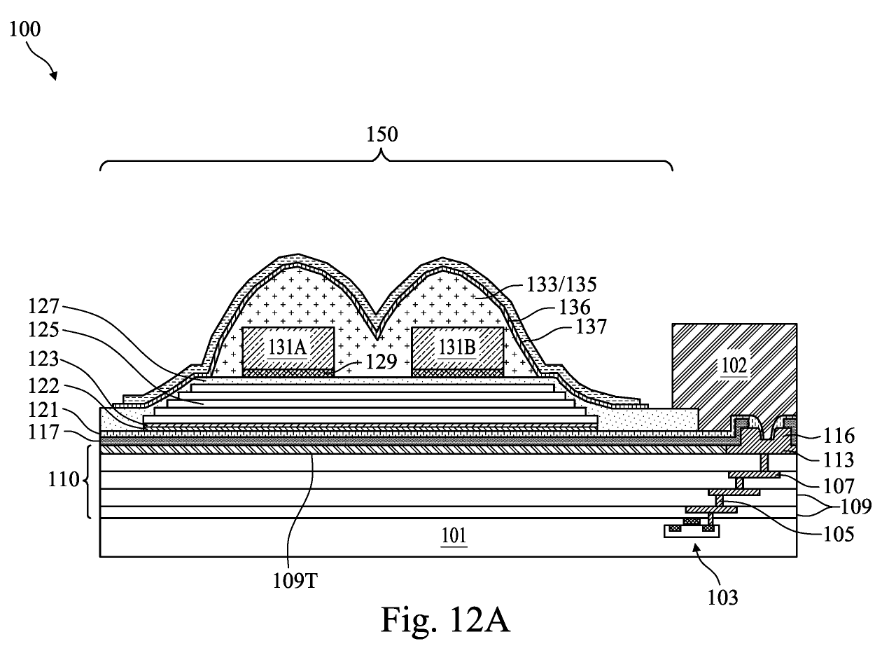

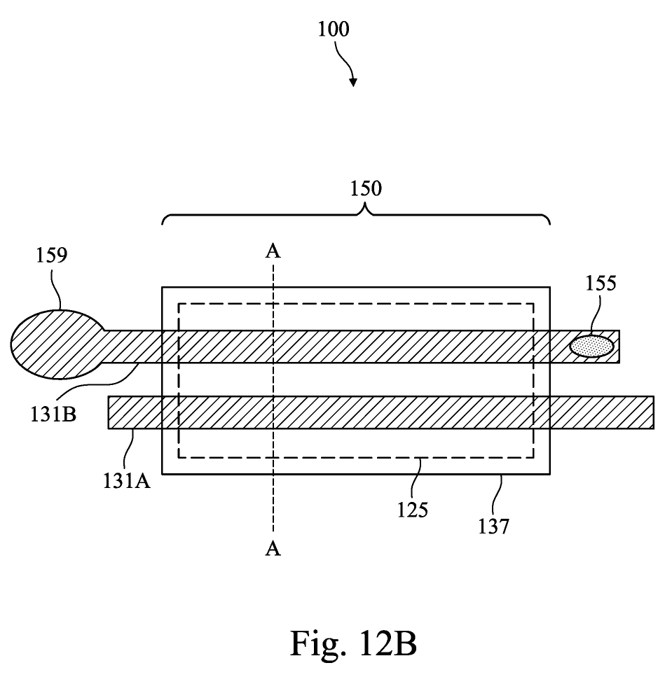

FIGS. 1 through 13 illustrate various views (e.g., cross-sectional and plan views) of a semiconductor device 100 at various stages of manufacturing, in accordance with an embodiment. The semiconductor device 100 includes inductive components (see, e.g., 150 in FIG. 12A) formed in a back-end-of-line (BEOL) process over passivation layer(s) of a semiconductor die. Note that for simplicity, not all features of the semiconductor device 100 are illustrated, and FIGS. 1 through 13 may illustrate only a portion of the semiconductor device 100.

FIG. 1 illustrates the semiconductor device 100 in an intermediate stage of manufacturing. The semiconductor device 100 in FIG. 1 is or includes a semiconductor die (also referred to as a die, or an integrated-circuit (IC) die). As illustrated in FIG. 1, the semiconductor device 100 includes a substrate 101, electrical components 103 formed in/on the substrate 101, an interconnect structure 110 over the substrate 101, a contact pad 116,, a first passivation layer 117, and a polymer layer 121.

The substrate 101 may be a semiconductor substrate, such as silicon, doped or undoped, or an active layer of a semiconductor-on-insulator (SOI) substrate. The semiconductor substrate 101 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Electrical components 103, such as transistors, diodes, capacitors, resistors, or the like, may be formed in and/or on the semiconductor substrate 101 and may be interconnected by the interconnect structures 110 to form functional circuits of the semiconductor die. The electrical components 103 may be formed using any suitable methods. The interconnect structure 110 includes dielectric layers 109 over the semiconductor substrate 101 and conductive features (e.g., vias 105 and conductive lines 107) formed in the dielectric layers 109. The dielectric layers 109 may be formed of a dielectric material (e.g., a low-k dielectric material) using a suitable formation method, such as chemical vapor deposition (CVD), physical vapor deposition (PVD), combinations thereof, or the like. The conductive features may be formed of a conductive material (e.g., copper) using a suitable formation method, such as deposition, damascene, dual damascene, or the like. FIG. 1 illustrates a top dielectric layer 109T (e.g., the topmost dielectric layer) of the interconnect structure 110, and a metallization pattern 113 (e.g., a copper pad) in the top dielectric layer 109T.

A contact pad 116 (also referred to as a conductive pad) is formed over and coupled to the metallization pattern 113. Throughout the discussion herein, unless otherwise specified, words such as “coupled” and “coupling” refer to electrical coupling, the word “conductive” means electrically conductive, and words such as “insulation” or “insulator” refer to electrical insulation/insulator.

The contact pad 116 is formed over and in electrical contact with the metallization pattern 113 in order to provide electrical connection to the functional circuits of the die. The contact pad 116 may comprise aluminum, copper, nickel, the like, or a combination thereof. The contact pad 116 may be formed using a deposition process, such as sputtering, to form a layer of conductive material. Next, portions of the layer of conductive material may be removed through a suitable process, such as photolithography and etching, to form the contact pad 116. However, any other suitable process may be utilized to form the contact pad 116.

The first passivation layer 117 may be formed over the contact pad 116 and the top dielectric layer 109T. The first passivation layer 117 may be formed of one or more suitable dielectric materials such as silicon oxide, silicon nitride, low-k dielectrics such as carbon doped oxides, extremely low-k dielectrics such as porous carbon doped silicon dioxide, a polymer such as polyimide, polybenzoxazole (PBO), benzocyclobutene (BCB), combination thereof, or the like. The first passivation layer 117 may be formed through a process such as CVD, although any suitable process may be utilized.

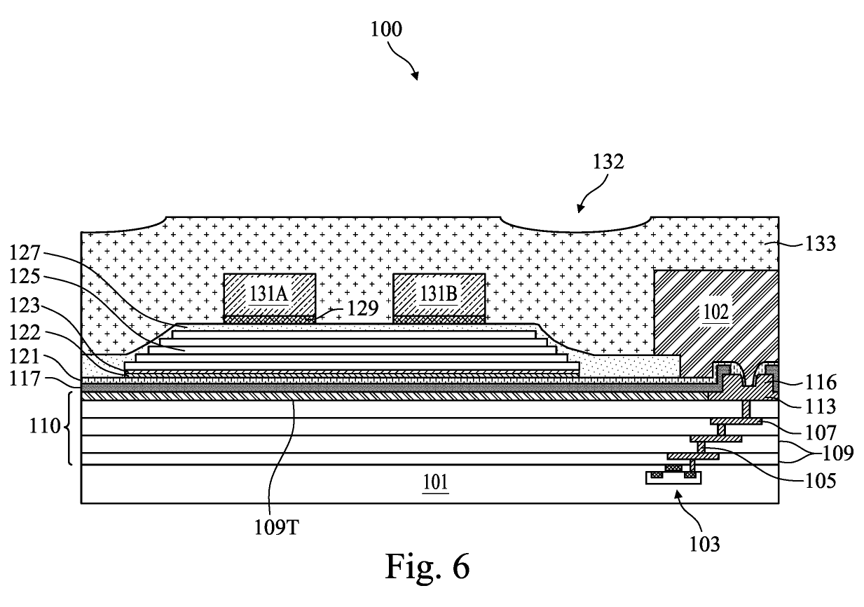

After the first passivation layer 117 is formed, an opening through the first passivation layer 117 is formed to expose at least a portion of the underlying contact pad 116. Next, the polymer layer 121 is formed over the contact pad 116 and the first passivation layer 117. In an embodiment, the polymer layer 121 is formed of a polyimide (PI) material, and may be deposited using a spin-coating method, or the like. Next, an opening is formed through the polymer layer 121 to expose the underlying contact pad 116, in order to allow for physical and electrical contact between the contact pad 116 and a subsequently formed post-passivation interconnect (PPI) structure 102 (see, e.g., FIG. 6). The opening may be formed through the polymer layer 121 by one or more photolithography and/or etching processes.

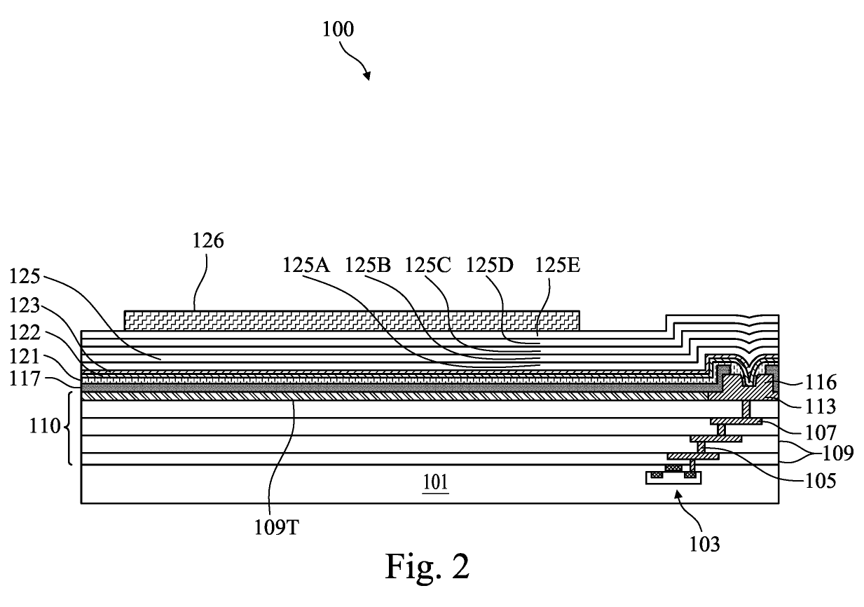

In FIG. 2, an adhesion layer 122 is formed over the polymer layer 121. In accordance with some embodiments, the adhesion layer 122 is formed of titanium, which has a good adhesion to the polymer layer 121. The adhesion layer 122 may be formed using Physical Vapor Deposition (PVD), Chemical Vapor Deposition (CVD), or the like. An insulation layer 123 is then formed over the adhesion layer 122. The insulation layer may comprise an inorganic material. In accordance with some embodiments, the insulation layer 123 is formed of silicon nitride, silicon oxynitride, or the like. The insulation layer 123 may be formed using Atomic Layer Deposition (ALD), CVD, Plasma Enhance Chemical Vapor Deposition (PECVD), or the like.

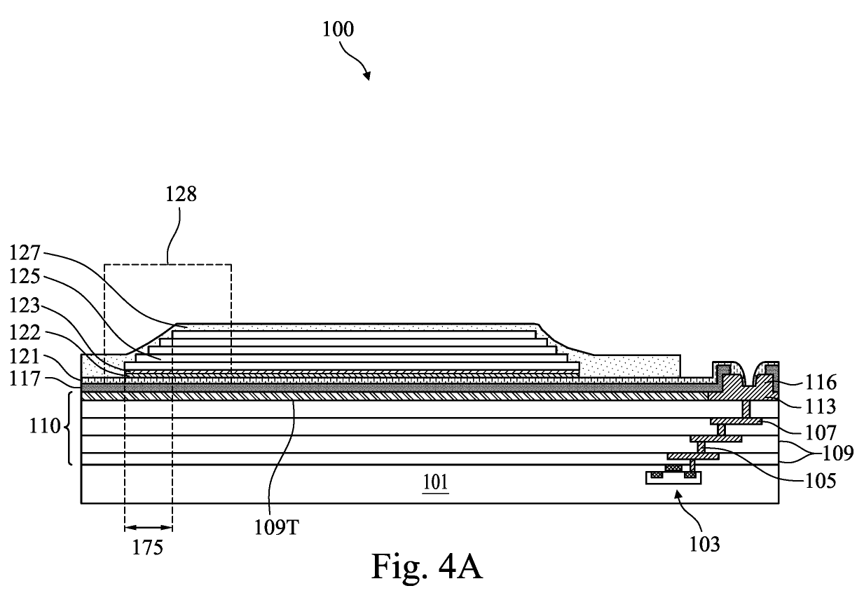

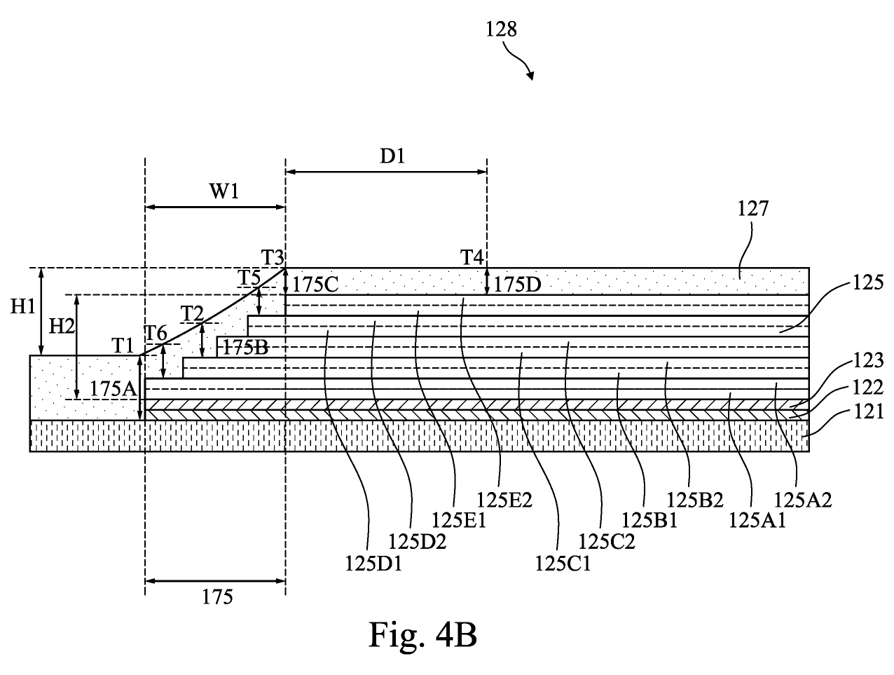

Next, a magnetic film 125 is formed over the insulation layer 123 and the substrate 101 using a blanket deposition process. In accordance with some embodiments, the magnetic film 125 includes a plurality of magnetic layers, e.g., magnetic film layer 125A, magnetic film layer 125B over the magnetic film layer 125A, magnetic film layer 125C over the magnetic film layer 125B, magnetic film layer 125D over the magnetic film layer 125C, and magnetic film layer 125E over the magnetic film layer 125D. Although five magnetic film layers 125A-E are shown in FIG. 2, any number of magnetic film layers may be formed to form the magnetic film 125 (which may also be referred to subsequently as a magnetic film stack). Each of the magnetic film layers 125A-E is a composite layer that comprises at least two sub-layers, with these sub-layers being alternatingly stacked to form the magnetic film 125 (e.g., the magnetic film sub-layers 125A1 and 125A2, the magnetic film sub-layers 125B1 and 125B2, the magnetic film sub-layers 125C1 and 125C2, the magnetic film sub-layers 125D1 and 125D2, and the magnetic film sub-layers 125E1 and 125E2 shown subsequently in FIG. 4B. In this way, each magnetic film sub-layer apart from the topmost sub-layer of the magnetic film layer 125E and the bottommost sub-layer of the magnetic film layer 125A is disposed between and in contact with other sub-layers of the magnetic film 125 that comprise a different material from a material of the magnetic film sub-layer.) These sub-layers may comprise cobalt zirconium tantalum (CoZrTa), oxidized CoZrTa, polyimide, adhesion promoter, or the like. When the sub-layers of each of the magnetic film layers 125A-E comprise a polyimide sub-layer, the polyimide sub-layer will be disposed below a topmost sub-layer of each of the magnetic film layers 125A-E. In other embodiments, the magnetic film layers 125A-E may comprise other magnetic material such as iron (Fe) compound, nickel (Ni) compound, or the like. The magnetic film layers 125A-E may formed using a deposition process such as CVD, PVD, ALD, or the like.

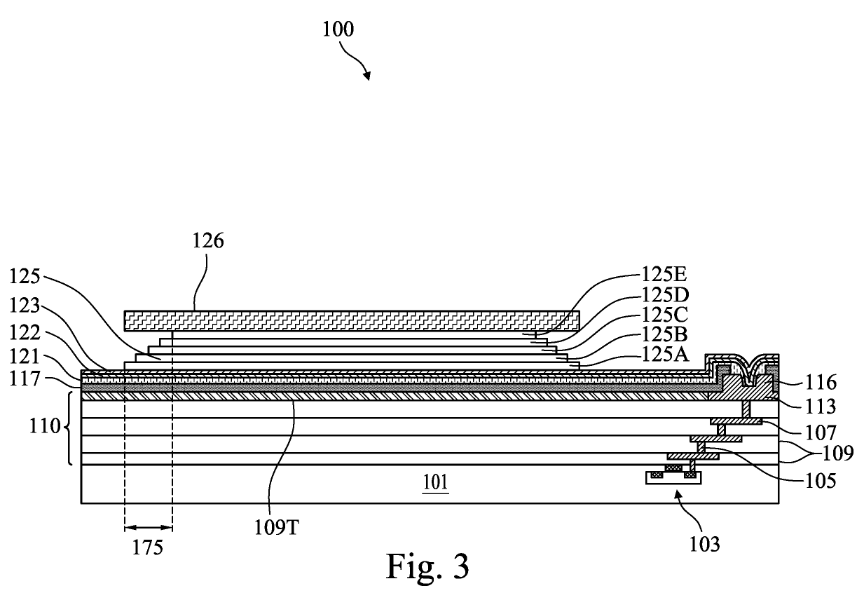

Referring further to FIG. 2, a mask layer 126 (e.g., a photoresist or hard mask) is formed over the magnetic film 125 and the substrate 101, such as over a top surface of the magnetic film layer 125E. The mask layer 126 is then patterned in order to form a mask to pattern the underlying magnetic film layers 125A-E. Additionally, the mask layer 126 may be patterned in such a way as to help shape the underlying magnetic film layers 125A-E in a subsequent process (shown in FIG. 3).

In FIG. 3, an etching process is performed to etch the magnetic film layers 125A-E using the mask layer 126 as an etch mask. In an embodiment the etching process is a wet etching process using etchants that are selective to the materials of the magnetic film layers 125A-E. For example, in an embodiment the etching process may use an etchant such as hydrochloric acid, nitric acid, or the like. The insulation layer 123 may act as an etch stop layer during the etching of the magnetic film layers 125A-E, and may prevent damage to underlying layers/structures.

In some embodiments, the wet etching process used to etch the magnetic film layers 125A-E is an isotropic etching process. The individual magnetic film layers (e.g., the magnetic film layer 125A, the magnetic film layer 125B, the magnetic film layer 125C, the magnetic film layer 125D, and the magnetic film layer 125E) will be etched at different times as they are each exposed by the removal of an overlying layer during the wet etching process. During the wet etching process, etching of exposed portions of the topmost magnetic film layer 125E (e.g., portions exposed by the patterned mask layer 126) will begin sooner than etching of the underlying layers of the magnetic film 125. Since the wet etching process is an isotropic etching process, the magnetic film layer 125E will also undergo lateral etching and undercut the mask layer 126. After the wet etch process has etched through a thickness of the exposed portions of the magnetic layer 125E, the underlying magnetic film layer 125D is exposed and is now etched isotropically (e.g., both vertical etching and lateral etching) as well. At the same time, the remaining magnetic film layer 125E under the mask layer 126 continues to be laterally etched such that it is laterally etched by a greater amount than the magnetic film layer 125D. After a thickness of the exposed portions of the magnetic layer 125D have been etched, the underlying magnetic film layer 125C is also exposed and is etched isotropically (e.g., both vertical etching and lateral etching) as well. At the same time, the remaining magnetic film layers 125E and 125D under the mask layer 126 continue to be laterally etched such that it is laterally etched by a greater amount than the underlying magnetic film layer 125C. The wet etching process continues the isotropic etching process (e.g., lateral and vertical etching) described above until all the magnetic film layers of the stack are patterned. As a result, the magnetic film layers further away from the substrate 101 (e.g., the magnetic film layer 125E) experience higher amounts of lateral etching than magnetic film layers closer to the substrate 101 (e.g., the magnetic film layer 125A).For example, in an embodiment, the magnetic film layer closest to the mask layer 126 (e.g., the magnetic film layer 125E) may undergo the highest amount of lateral etching and undercut the mask layer 126 by a greatest distance than all the underlying magnetic film layers. The amount that each of the magnetic film layers 125A-E undercut the mask layer 126 decreases in a direction towards the substrate 101. As a result, an isotropic etching process may be used to define a stairstep pattern 175. The stairstep pattern 175 may have a step height equal to a thickness of each of the individual magnetic film layers 125A-E.

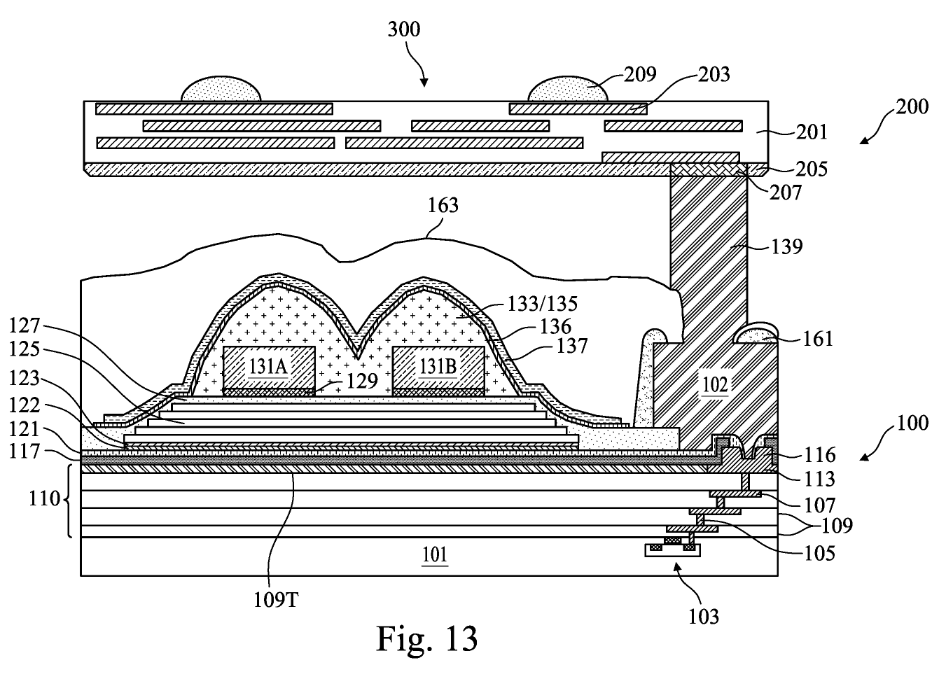

In FIG. 4A, the patterned mask layer 126 used for patterning the magnetic film layers 125A-E is then removed by a suitable process (e.g., ashing). Next, an etching process is performed to pattern the adhesion layer 122 and the insulation layer 123. For example, a patterned mask layer (e.g., a photoresist, not separately illustrated) is formed over the adhesion layer 122, the insulation layer 123 and over the patterned magnetic film 125, and is used as an etching mask to pattern the adhesion layer 122 and the insulation layer 123 in a suitable etching process (e.g., an anisotropic etching process). After the patterning of the adhesion layer 122 and the insulation layer 123, portions of the adhesion layer 122 and the insulation layer 123 disposed in the region of the inductive component 150 (see, e.g., FIG. 13) remain, and other portions of the adhesion layer 122 and the insulation layer 123 (e.g., disposed outside the region of the inductive component 150) are removed. The patterned mask layer is then removed by a suitable process (e.g., ashing).

Still referring to FIG. 4A, a polymer layer 127 is then formed over the magnetic film 125, the insulation layer 123, and the polymer layer 121. In some embodiments, the polymer layer 127 is formed of a polyimide (PI) material, such as a photosensitive PI material. In an embodiment, the polymer layer 127 is an organic material. The polymer layer 127 may be formed by a suitable deposition technique such as spin-coating, or the like. Next, the polymer layer 127 is patterned, e.g., by a photolithography process. For example, a mask layer with patterns is positioned over the polymer layer 127, and a light source is projected on the polymer layer 127 through the mask layer. The patterns of the mask layer allow light to pass through the mask layer and reach certain portions of the polymer layer 127, and block the light from reaching other portions of the polymer layer 127. After being exposed to the light source, the polymer layer 127 is developed by using a developer (e.g., a chemical), which removes exposed or unexposed portions of the polymer layer 127, depending on whether the polymer layer 127 is a negative or positive type of photosensitive material.

FIG. 4B shows detailed view of a region 128 of the semiconductor device 100 that was illustrated in FIG. 4A. In FIG. 4B, the polymer layer 127 is shown disposed over the magnetic film 125, including over the stairstep pattern 175 of the sidewall of the magnetic film 125. A first portion of the polymer layer 127 that overlaps the stairstep pattern 175 of the sidewall of the magnetic film 125 has a sloping top surface. In an embodiment, a thickness of the polymer layer 127 above a center of each step of the stairstep pattern 175 increases in a direction from a topmost step of the stairstep pattern 175 towards a bottommost step of the stairstep pattern 175. In an embodiment, a vertical height H1 between a topmost surface of the polymer layer 127 (e.g., over the magnetic film layer 125E) and a bottommost point of all top surfaces of the polymer layer 127 (e.g., a point adjacent to and not overlapping the magnetic film 125) is in a range from 1µm to 20µm. In an embodiment, a vertical height H2 between a topmost surface of the magnetic film 125 (e.g., a top surface of the magnetic film layer 125E) and a bottommost surface of the magnetic film 125 (e.g., a bottom surface of the magnetic film layer 125A) is greater than the height H1. In an embodiment, the height H2 of the magnetic film 125 is in a range from 1 µm to 20 µm. In an embodiment, a width W1 of the stairstep pattern 175 from a first sidewall of the magnetic film layer 125A to a second sidewall of the magnetic film layer 125E is in a range from 1 µm to 3 µm, wherein the width W1 is measured in a direction that is orthogonal to the first sidewall and the second sidewall of the magnetic film layer 125A.

In an embodiment, the polymer layer 127 has a thickness T1 at a first location 175A at the outer edge (e.g., the first sidewall) of the bottommost magnetic film layer 125A. The thickness T1 is measured from a bottom surface of the polymer layer 127 to a top surface of the polymer layer 127, and the thickness T1 is in a range from 2 µm to 3.5 µm. Advantages can be achieved as a result of forming the polymer layer 127 over the magnetic film 125, wherein at the first location 175A at the outer edge of the magnetic film layer 125A, the polymer layer 127 has the thickness T1 that is in a range from 2 µm to 3.5 µm. For example, the polymer layer 127 having a thickness T1 that is smaller than 2 µm at the first location 175A may result in poor adhesion between a subsequently formed insulation layer 136 (described in FIG. 12A) and the polymer layer 127, which results in an increased risk of delamination and cracking of the insulation layer 136 that overlaps the stairstep pattern 175 of the magnetic film 125. In addition, the polymer layer 127 having a thickness T1 that is greater than 3.5 µm at the first location 175A may result in induction devices that have degraded electrical properties that are only capable of achieving low inductance values.

In an embodiment, the polymer layer 127 has a vertical thickness T2 at a second location 175B that is at a center point of the stairstep pattern 175 of the magnetic layer 125. The thickness T2 is measured from a top surface of the polymer layer 127 to a top surface of the stairstep pattern 175, and the thickness T2 is in a range from 0.7 µm to 2.4 µm. The second location 175B may be disposed at a midpoint of a lateral span of the stairstep pattern 175. Advantages can be achieved as a result of forming the polymer layer 127 over the magnetic film 125, wherein at the second location 175B at the center point of the stairstep pattern 175 of the magnetic layer 125, the polymer layer 127 has the thickness T2 that is in a range from 0.7 µm to 2.4 µm. For example, the polymer layer 127 having a thickness T2 that is smaller than 0.7 µm at the second location 175B may result in poor adhesion between the subsequently formed insulation layer 136 (described in FIG. 12A) and the polymer layer 127, which results in an increased risk of delamination and cracking of the insulation layer 136 that overlaps the stairstep pattern 175 of the magnetic film 125. In addition, the polymer layer 127 having a thickness T2 that is greater than 2.4 µm at the second location 175B may result in induction devices that have degraded electrical properties that are only capable of achieving low inductance values.

In an embodiment, the polymer layer 127 has a vertical thickness T3 at a third location 175C that is directly above the second sidewall of the topmost magnetic film layer 125E. The thickness T3 may be measured from a top surface of the polymer layer 127 to a top surface of the magnetic film layer 125E, and the thickness T3 is in a range from 0.2 µm to 1.6 µm. Advantages can be achieved as a result of forming the polymer layer 127 over the magnetic film 125, wherein at the third location 175C that is directly above the second sidewall of the magnetic film layer 125E, the thickness T3 is in a range from 0.2 µm to 1.6 µm. For example, the polymer layer 127 having a thickness T3 that is smaller than 0.2 µm at the third location 175C may result in poor adhesion between the subsequently formed insulation layer 136 (described in FIG. 12A) and the polymer layer 127, which results in an increased risk of delamination and cracking of the insulation layer 136 that overlaps the stairstep pattern 175 of the magnetic film 125. In addition, the polymer layer 127 having a thickness T3 that is greater than 1.6 µm at the third location 175C may result in induction devices that have degraded electrical properties that are only capable of achieving low inductance values.

In an embodiment, the polymer layer 127 has a thickness T4 directly above a fourth location 175D on a topmost surface of the magnetic film layer 125E. The fourth location 175D is a lateral distance D1 away from the second sidewall of the magnetic film layer 125E, and the distance D1 is less than 10 µm. In an embodiment, the distance D1 is greater than the width W1 of the stairstep pattern 175. In an embodiment, the thickness T4 is in a range from 0.4 µm to 1.0 µm. Advantages can be achieved as a result of forming the polymer layer 127 over the magnetic film 125, wherein at the fourth location 175D the thickness T4 is in a range from 0.4 µm to 1.0 µm. For example, the polymer layer 127 having a thickness T4 that is smaller than 0.4 µm at the fourth location 175D may result in poor adhesion between the subsequently formed insulation layer 136 (described in FIG. 12A) and the polymer layer 127, which results in an increased risk of delamination and cracking of the insulation layer 136 that overlaps the magnetic film 125. In addition, the polymer layer 127 having a thickness T4 that is greater than 1.0 µm at the fourth location 175D may result in induction devices that have degraded electrical properties that are only capable of achieving low inductance values.

In an embodiment, a thickness of the polymer layer 127 increases in a direction from a topmost step of the stairstep pattern 175 towards a bottommost step of the stairstep pattern 175. For example, a thickness T5 of the polymer layer 127 directly above and in physical contact with a top surface of a step of the magnetic film layer 125D is smaller than a thickness T6 of the polymer layer 127 directly above and in physical contact with a top surface of a step of the magnetic film layer 125A. In an embodiment, the thickness T2 is smaller than the thickness T6 and greater than the thickness T5. The thicknesses of different portions of the polymer layer 127 (e.g., the thickness T1-T6) can be controlled by varying the coating speed of the spin-coating tool during deposition of the polymer layer 127. For example, faster coating speeds will result in the different portions of the polymer layer having smaller thicknesses and slower coating speeds will result in the different portions of the polymer layer having larger thicknesses. Therefore, to obtain the thicknesses T1-T6 described above, an optimal range of coating speeds is used during the spin-coating process. In an embodiment, the thickness T4 may be greater than the thickness T3. Advantages can be achieved as a result of forming the polymer layer 127 over the magnetic film 125, wherein the thickness of the polymer layer 127 increases in a direction from a topmost step of the stairstep pattern 175 towards a bottommost step of the stairstep pattern 175. These advantages include improved adhesion between the subsequently formed insulation layer 136 (described in FIG. 12A) and the polymer layer 127, which results in a reduced risk of delamination and cracking of the insulation layer 136 that overlaps the magnetic film 125.

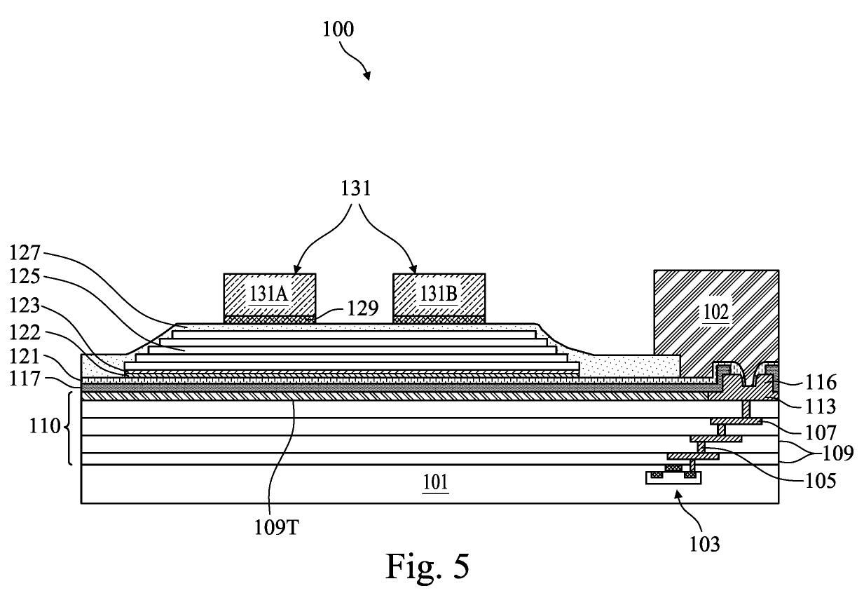

In FIG. 5, a post-passivation interconnect (PPI) structure 102 is formed over and electrically coupled to the contact pad 116. In addition, conductive features 131 are also formed over the magnetic film 125. The conductive features 131 may be formed in the same processing step for forming the PPI structure 102, or may be formed by another formation process similar to that for forming the PPI structure 102 that is performed before or after the PPI structure 102 is formed. The PPI structure 102 may include a conductive line (e.g., copper line) extending parallel to the upper surface of the substrate 101 for re-routing the electrical connection to the contact pad 116 to a different location, and may include PPI pads (e.g., copper pads) for forming conductive connector (e.g., copper pillars) thereon. For simplicity, FIG. 5 shows an example where the PPI structure 102 is a PPI pad formed directly over the contact pad 116. In some embodiments, to form the PPI structure 102, a seed layer is formed over the polymer layers 121/127 and over the contact pad 116. The seed layer may comprise a metal such as copper, titanium, or the like and is deposited using Physical Vapor Deposition (PVD), or the like. A first plating mask (e.g., a photoresist layer) is formed over the seed layer. The first plating mask is then patterned to form an opening over the contact pad 116.A conductive material, e.g., copper, is then formed in the opening using a plating process, or the like, to form the PPI structure 102. The first plating mask is then removed after the PPI structure is formed. FIG. 5 further illustrates a first conductive feature 131A and a second conductive feature 131B, which may be collectively referred to as the conductive features 131. The conductive features 131 may also be referred to as conductive coils or conductive traces subsequently. The conductive features 131 are formed over the polymer layer 127 and over (e.g., directly over) the magnetic film 125 in the region of the inductive component. The conductive features 131 may be formed in the same processing step for forming the PPI structure 102 (therefor may also be considered as PPI structures), or may be formed by another formation process similar to that for forming the PPI structure 102. The first conductive feature 131A and the second conductive feature 131B may be conductive patterns (e.g., parallel conductive lines) and may be used to form an inductive component. To form the conductive features 131, a seed layer 129 is formed over the polymer layer 127 using Physical Vapor Deposition (PVD), or the like. In accordance with some embodiments, seed layer 129 is a composite layer comprising a plurality of layers. For example, seed layer 129 may include a lower layer and an upper layer, wherein the lower layer may include a titanium layer, and the materials of the upper layer may include copper or a copper alloy. In accordance with alternative embodiments, seed layer 129 is a single layer, which may be a copper layer, for example.

After the formation of the seed layer 129, a second plating mask (e.g., a photoresist) is formed over the semiconductor device 100 and patterned to form openings, through which some portions of the seed layer 129 are exposed. Next, a plating process is performed to form the conductive features 131. The conductive features 131 may be formed of a metal or a metal alloy such as copper or a copper alloy, or the like.

After the plating process, the second plating mask is removed using a suitable stripping process. The portions of the seed layer 129 covered by the second plating mask are then removed using a suitable etching process, while the portions of the seed layer 129 covered by the conductive features 131 remain un-removed.

In FIG. 6, a polymer layer 133 is formed over the polymer layer 127, the conductive features 131, and the PPI structure 102. In an embodiment, the polymer layer 133 surrounds each of the conductive features 131 and the seed layer 129. In an embodiment, top surfaces of the polymer layer 133 are higher than top surfaces of the conductive features 131 and the PPI structure 102. In the example embodiment, the polymer layer 133 is formed of a photosensitive polyimide material, such as PBO, or the like, and may be formed by a suitable method, such as spin coating. FIG. 6 further illustrates recesses 132 at the upper surfaces of the polymer layer 133, which are formed due to differences in the pattern density (e.g., density of the conductive features 131 or the PPI structure 102) in different areas of the semiconductor device 100.

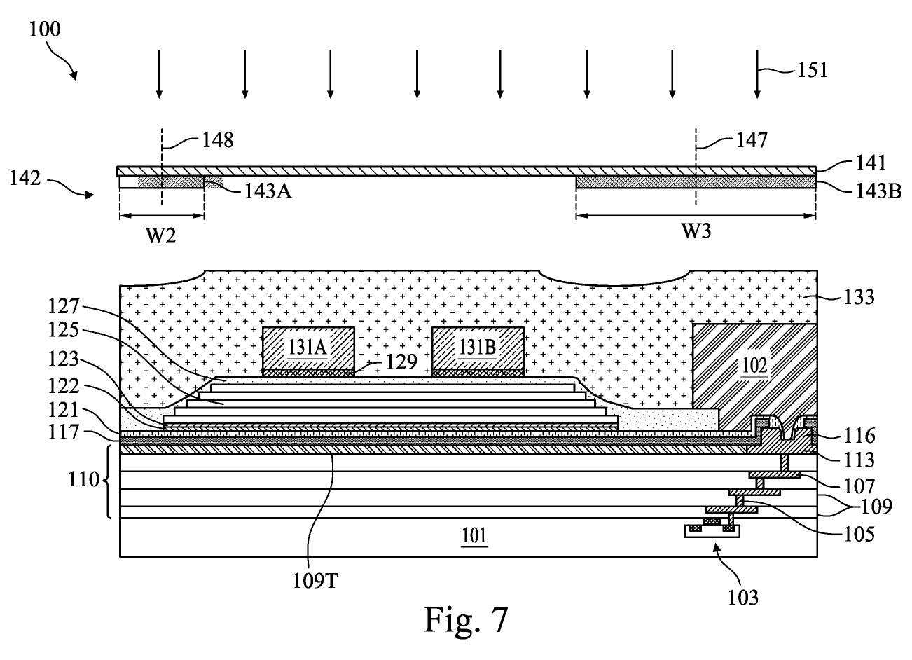

In FIG. 7, a light source 151 is projected onto the polymer layer 133 through a mask layer 142. The mask layer 142 includes a transparent layer 141 (e.g., a glass layer, or a quartz layer) and non-transparent patterns 143A and 143B attached to the transparent layer 141. The non-transparent patterns 143A and 143B are formed of a material(s) that is non-transparent to the light source 151, which light source 151 includes lights having one or more wavelengths. The non-transparent patterns 143 may be collectively referred to as non-transparent patterns or light-blocking patterns. The processing of FIG. 7 may also be referred to as a first exposure process for the polymer layer 133.

In the example of FIG. 7, the non-transparent patterns 143 are formed at certain locations of the mask layer 142 such that during the first exposure process for the polymer layer 133, the non-transparent patterns 143A are over and at the left side of the conductive feature 131A, and the non-transparent pattern 143B is over and at the right side of the conductive feature 131B. In the illustrated embodiment, the non-transparent patterns 143A has a width W2 and a center axis 148. The non-transparent pattern 143B has a width W3 and a center axis 147.

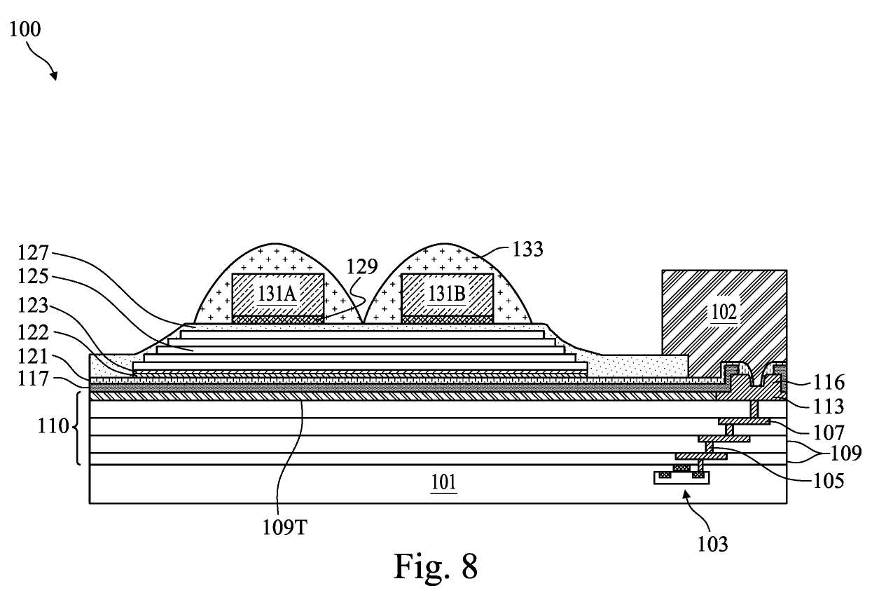

Next, in FIG. 8, the polymer layer 133 is developed using a developer (e.g., a chemical). In some embodiments, the polymer layer 133 is a negative photosensitive material, such that unexposed portions are soluble to the developer. FIG. 8 illustrates an example cross-section of the polymer layer 133 after the developing process. As illustrated in FIG. 8, different portions of the polymer layer 133 with different sizes are removed at different locations. For example, portions of the polymer layer may remain over each of the conductive feature 131A and the conductive feature 131B. In some embodiments, the locations and the dimensions (e.g., widths) of the non-transparent patterns 143 of the mask layers 142, as well as the exposure time/energy, among other process parameters, are adjusted to achieve a target profile for the polymer layer 133. After the developing process of FIG. 8, the patterned polymer layer 133 may be cured at a temperature that is in a range from 100 °C to 400 °C for a duration that is in a range from 2 hours to 15 hours.

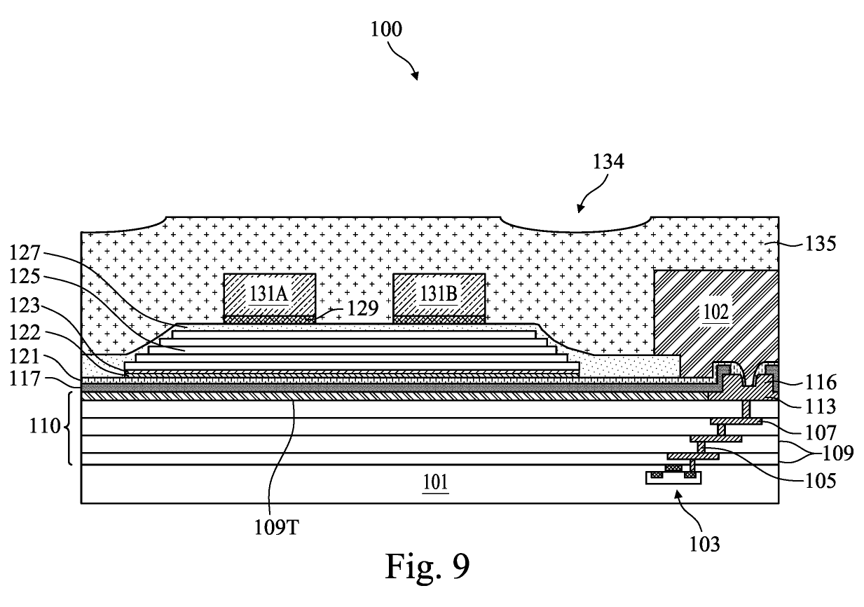

In FIG. 9, a polymer layer 135 is formed over the polymer layer 127, the conductive features 131, the PPI structure 102, and the remaining portions of the polymer layer 133. In an embodiment, the polymer layer 135 surrounds each of the conductive features 131, the seed layer 129, and the remaining portions of the polymer layer 133. In an embodiment, top surfaces of the polymer layer 135 are higher than top surfaces of the conductive features 131 and the PPI structure 102. In the example embodiment, the polymer layer 135 is formed of a photosensitive polyimide material, such as PBO or BL 300 material, and may be formed by a suitable method, such as spin coating. In an embodiment, a material of the polymer layer 133 and a material of the polymer layer 135 are the same. FIG. 9 further illustrates recesses 134 at the upper surfaces of the polymer layer 135, which are formed due to differences in the pattern density (e.g., density of the conductive features 131 or the PPI structure 102) in different areas of the semiconductor device 100.

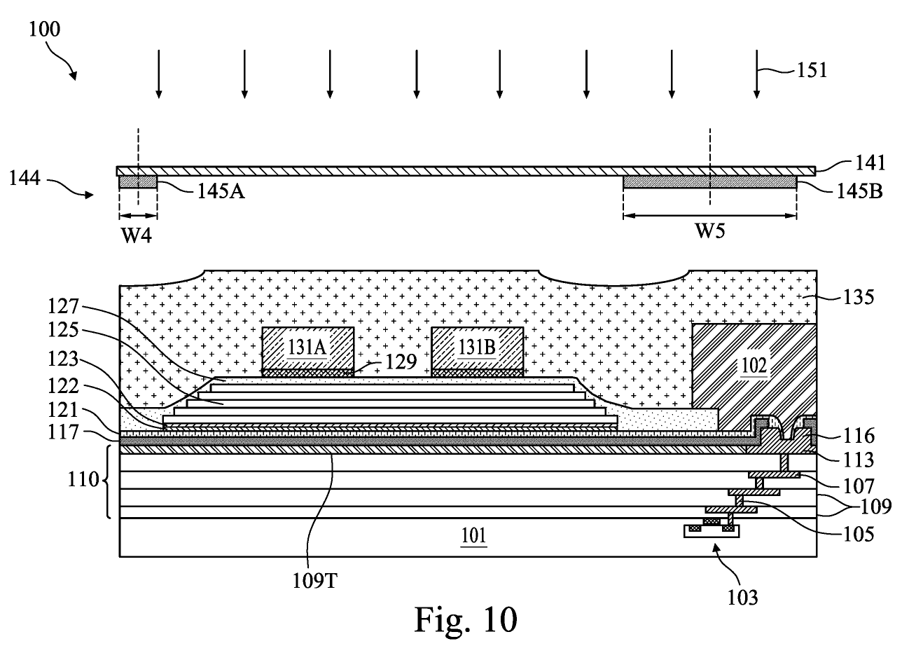

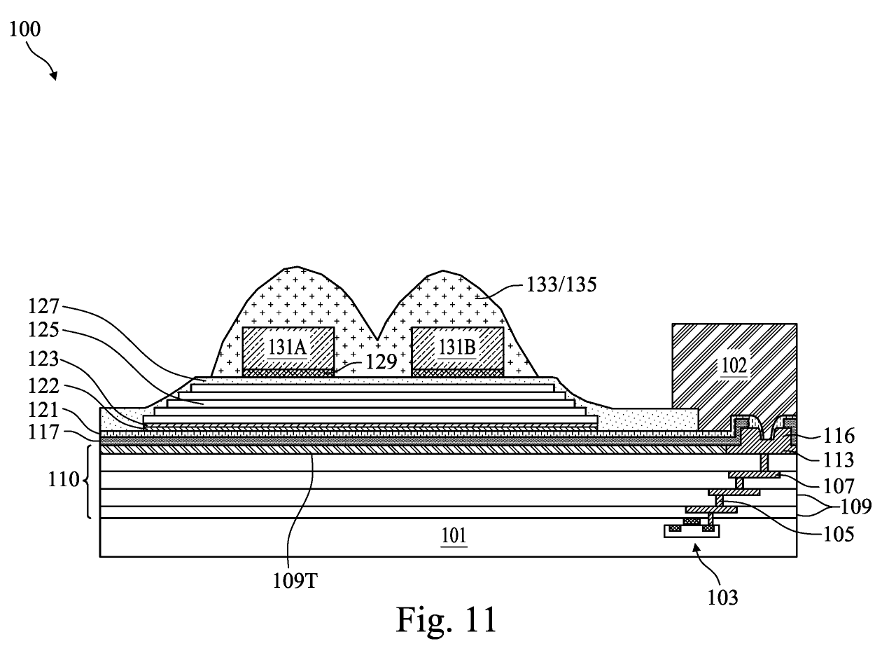

Next, in FIG. 10, the polymer layer 135 and the polymer layer 133 are exposed to a light source. In particular, the light source 151 is projected onto the polymer layer 135 and the polymer layer 133 through a mask layer 144, which includes a transparent layer 141 and non-transparent patterns 145A and 145B (may be collectively referred to as non-transparent patterns 145). The non-transparent pattern 145A corresponds to the non-transparent pattern 143A in FIG. 7, but with a width W4 that is smaller than the width W2 of the non-transparent pattern 143A. In some embodiments, the center axis of the non-transparent pattern 145A is the same as the center axis 148 of the non-transparent pattern 143A. In other words, the non-transparent patterns 143A and 145A are at the same location (e.g., having the same center axis 148) but having different widths. Similarly, the non-transparent pattern 145B corresponds to the non-transparent pattern 143B in FIG. 7, but with a width W5 that is smaller than the width W3 of the non-transparent pattern 143B. In some embodiments, the center axis of the non-transparent pattern 145B is the same as the center axis 147 of the non-transparent pattern 143B. The exposure energy of the exposure process in FIG. 10 may be similar to that in FIG. 7, and may be adjusted to achieved a target profile for the polymer layer 135 and the polymer layer 133 (see FIG. 11) after the developing process described subsequently in FIG. 11. The processing of FIG. 10 may also be referred to as a second exposure process for the polymer layer 133.

In FIG. 11, the polymer layer 133 and the polymer layer 135 are developed using a developer (e.g., a chemical). In some embodiments, the polymer layer 133 and the polymer layer 135 are a negative photosensitive material, such that unexposed portions are soluble to the developer. FIG. 11 illustrates an example cross-section of the polymer layer 133 and the polymer layer 135 after the developing process. As illustrated in FIG. 11, different portions of the polymer layer 133 and the polymer layer 135 with different sizes may be removed at different locations, due to, e.g., the different portions of the polymer layer 133 and the polymer layer 135 being exposed for different durations. In some embodiments, the locations and the dimensions (e.g., widths) of the non-transparent patterns 143/145 of the mask layers 142/144, as well as the exposure time/energy, among other process parameters, are adjusted to achieve a target profile for the polymer layer 133 and the polymer layer 135.

In FIG. 12A, an insulation layer 136 and a magnetic film 137 are formed successively over the polymer layer 133/135 and the polymer layer 127. The insulation layer 136 may comprise an inorganic material. In accordance with some embodiments, the insulation layer 136 is formed of silicon nitride, silicon oxynitride, or the like. The insulation layer 36 may be formed using ALD, CVD, Plasma Enhance Chemical Vapor Deposition (PECVD), or the like. The magnetic film 137 may comprise cobalt zirconium tantalum (CoZrTa). In other embodiments, other magnetic material, such as iron (Fe) compound, nickel (Ni) compound, or the like, may also be used to form the magnetic film 137. The magnetic film 137 may be formed using a deposition process such as CVD, PVD, ALD, or the like. The insulation layer 136 and the magnetic film 137 are patterned to remove portions outside of the region of the inductive component 150. The remaining portions of the insulation layer 136 and the magnetic film 137, together with the conductive features 131A/131B, and the underlying insulation layer 123 and the underlying magnetic film 125, form the inductive component 150. In some embodiments, the insulation layer 136 functions as an etch stop layer for the magnetic film 137, such that the etching process used for patterning the magnetic film 137 does not damage the underlying layers/structures. As illustrated in FIG. 12A, the magnetic films 125 and 137 surround the conductive features 131, and form a closed magnetic loop when an electrical current is supplied to the conductive features 131.

FIG. 12B illustrates a plan view (e.g., when viewed from the top of the semiconductor device 100) of the semiconductor device 100 shown in FIG. 12A. Note that for simplicity, not all features are illustrated in FIG. 12B. FIG. 12A corresponds to the cross-sectional view along cross-section A-A in FIG. 12B. As illustrated in FIG. 12B, the conductive features 131A and 131B (e.g., conductive lines) may extend beyond the region of the inductive component 150. Note that the disclosed inductive component 150 includes conductive features (e.g., parallel conductive lines) surrounded by magnetic material (e.g., 125 and 137). FIG. 12B also illustrates a via 155 formed under the conductive feature 131B and electrically couples the conductive feature 131B to the contact pad 116 (e.g., an aluminum pad) formed in the first passivation layer 117, which contact pad 116 is coupled to the metallization pattern 113 (e.g., a conductive line) in the top dielectric layer 109T of the interconnect structure 110. The metallization pattern 113 is electrically coupled to other conductive features of the interconnect structure 110. FIG. 12B further illustrates a conductive bump 159 (e.g., a copper bump, a copper pillar) formed over the conductive feature 131B. The conductive bump 159 and the via 155 provide electrical connection to the conductive feature 131B. The conductive feature 131A may be electrically coupled to other conductive features similarly (e.g., through vias or conductive bumps), details are not repeated.

FIG. 13 illustrates a cross-sectional view of a semiconductor structure 300, in accordance with an embodiment. The semiconductor structure 300 is formed by bonding the semiconductor device 100 of FIGS. 12A and 12B to a substrate 200. In some embodiments, to form the semiconductor structure 300, a conductive connector 139 (e.g., a copper pillar) is formed on the PPI structure 102 of the semiconductor device 100, and is bonded to a conductive pattern (e.g., a copper pad) of the substrate 200 through a solder region 207. The substrate 200 may be, e.g., a printed circuit board, an interposer, or the like. The substrate 200 includes dielectric layers 201 and conductive features 203 (e.g., conductive lines, vias, conductive pads) formed in the dielectric layers 201. A passivation layer 205, e.g., a solder resist layer, or a polymer layer, is formed on a lower surface of the substrate 200, and conductive connectors 209 (e.g., solder balls) are formed on an upper surface of the substrate 200. FIG. 13 further illustrates a passivation layer 161 (e.g., a polymer layer) formed along sidewalls and the upper surface of the PPI structure 102, and a molding material 163 on the semiconductor device 100 around the conductive connector 139.

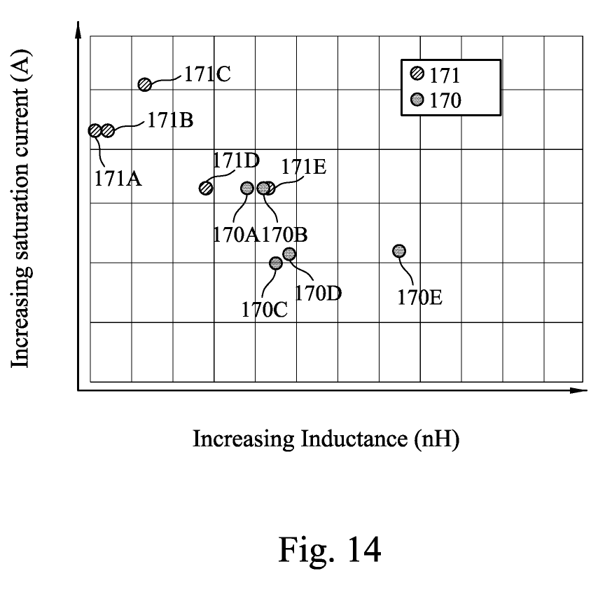

FIG. 14 shows traces of saturation current versus inductance for different example inductors. The inductors 170A-E indicate inductors that each comprise the polymer layer 127 having the thickness T1 at the first location 175A at the outer edge (e.g., the first sidewall) of the bottommost magnetic film layer 125A, wherein the thickness T1 is measured from a bottom surface of the polymer layer 127 to a top surface of the polymer layer 127, and wherein the thickness T1 is in a range from 2 µm to 3.5 µm. The inductors 170A-E each comprise the polymer layer 127 having the vertical thickness T2 at the second location 175B that is at a center point of the stairstep pattern 175 of the magnetic layer 125, and wherein the thickness T2 is measured from a top surface of the polymer layer 127 to a top surface of the stairstep pattern 175, and wherein the thickness T2 is in a range from 0.7 µm to 2.4 µm. The inductors 170A-E also each comprise the polymer layer 127 having the vertical thickness T3 at the third location 175C that is directly above the second sidewall of the magnetic film layer 125E, wherein the thickness T3 is in a range from 0.2 µm to 1.6 µm. The inductors 170A-E also each comprise the polymer layer 127 having the thickness T4 directly above the fourth location 175D on a topmost surface of the magnetic film layer 125E, wherein the fourth location 175D is a distance D1 away from the second sidewall of the magnetic film layer 125E, wherein the distance D1 is less than 10 µm, and the thickness T4 is in a range from 0.4 µm to 1.0 µm.

The inductors 171A-E indicate inductors that each comprise the polymer layer 127 having a thickness greater than 3.5 µm (e.g., greater than the thickness T1) at the first location 175A at the outer edge (e.g., the first sidewall) of the magnetic film layer 125A, wherein the thickness is measured from a bottom surface of the polymer layer 127 to a top surface of the polymer layer 127. The inductors 171A-E each comprise the polymer layer 127 having a vertical thickness greater than 2.4 µm (e.g. greater than the thickness T2) at the second location 175B that is at a center point of the stairstep pattern 175 of the magnetic layer 125, and wherein the thickness is measured from a top surface of the polymer layer 127 to a top surface of the stairstep pattern 175. The inductors 171A-E also each comprise the polymer layer 127 having a vertical thickness greater than 1.6 µm (e.g., greater than the thickness T3) at the third location 175C that is directly above the second sidewall of the magnetic film layer 125E. The inductors 171A-E also each comprise the polymer layer 127 having a thickness greater than 1.0 µm (e.g., greater than the thickness T4) directly above the fourth location 175D on a topmost surface of the magnetic film layer 125E. FIG. 14 illustrates that the inductors 170A-E exhibit better electrical properties and can achieve higher inductances than the inductors 171A-E.

The embodiments of the present disclosure have some advantageous features. The embodiments include a method applied to the forming of an inductive component over a passivation layer of a semiconductor die. Forming the inductive component includes forming a first magnetic film over the passivation layer, and performing an etching process to cause a sidewall of the first magnetic film to have a stairstep pattern. A first polymer layer is then formed over the first magnetic film, such that a first portion of the first polymer layer that overlaps the stairstep pattern has a sloping top surface. In addition, a thickness of the first polymer layer above a center point of a top surface of each step of the stairstep pattern increases in a direction from a topmost step of the stairstep pattern towards a bottommost step of the stairstep pattern. A second polymer layer is formed over the first polymer layer. A first insulation layer is then formed over the second polymer layer and the first polymer layer. As a result, this allows for better adhesion between the first insulation layer and the first polymer layer, which results in a reduced risk of delamination and cracking of the first insulation layer that overlaps the stairstep pattern of the first magnetic film. In addition, one or more embodiments disclosed herein may result in induction devices with improved electrical properties and the allowance of these induction devices to achieve higher inductance values.

In accordance with an embodiment, a method of forming a semiconductor device includes forming a first insulation layer over a substrate; depositing a first stack of magnetic layers over the first insulation layer; etching the first stack of magnetic layers such that a sidewall of the first stack of magnetic layers forms a stairstep pattern; forming a first photosensitive layer over the first stack of magnetic layers, the first insulation layer, and the substrate, where a thickness of the first photosensitive layer above a center of a first step of the stairstep pattern is different from a thickness of the first photosensitive layer above a center of a second step of the stairstep pattern; forming a first conductive feature over the first photosensitive layer; depositing a second insulation layer over the first photosensitive layer and the first conductive feature; and depositing a second magnetic layer over the second insulation layer. In an embodiment, the first stack of magnetic layers and the second magnetic layer each include cobalt zirconium tantalum (CoZrTa). In an embodiment, the second insulating layer includes silicon nitride. In an embodiment, the first photosensitive layer includes a polymer. In an embodiment, the first photosensitive layer has a first thickness that is in a range from 2 µm to 3.5 µm at a first location, the first location being at an outermost edge of the first stack of magnetic layers, where the first thickness is measured from a bottom surface of the first photosensitive layer to a top surface of the first photosensitive layer. In an embodiment, the first photosensitive layer has a second thickness in a range from 0.7 µm to 2.4 µm at a second location, the second location being at a center of the stairstep pattern, where the second thickness is measured from a top surface of the first photosensitive layer to a top surface of the stairstep pattern. In an embodiment, the first photosensitive layer above a third location on a topmost surface of the first stack of magnetic layers has a third thickness that is in a range from 0.4 µm to 1.0 µm.

In accordance with an embodiment, a method of forming a semiconductor device includes forming an inductive component over a substrate, including depositing a first inorganic layer over the substrate; forming a first stack of magnetic layers over the first inorganic layer; patterning the first stack of magnetic layers such that a sidewall of the first stack of magnetic layers forms a stairstep pattern; forming a first organic layer over the first stack of magnetic layers and the substrate, where the first organic layer is in physical contact with the stairstep pattern; forming a first conductive feature over the first organic layer; forming a second organic layer over the first organic layer and the first conductive feature; and forming a second inorganic layer over the second organic layer and the first organic layer. In an embodiment, a first vertical height between a topmost surface of the first organic layer and a bottommost point of all top surfaces of the first organic layer is smaller than a second vertical height between a topmost surface of the first stack of magnetic layers and a bottommost surface of the first stack of magnetic layers. In an embodiment, the second organic layer and the first organic layer include polymers. In an embodiment, forming the first organic layer includes using a spin-coating process to deposit the first organic layer over the first stack of magnetic layers and the substrate. In an embodiment, after forming the first organic layer, a first portion of the first organic layer that overlaps the stairstep pattern of the first stack of magnetic layers has a sloping top surface. In an embodiment, a first thickness of the first organic layer directly above a top surface of a topmost step of the stairstep pattern is smaller than a second thickness of the first organic layer directly above a top surface of a bottommost step of the stairstep pattern. In an embodiment, the first organic layer has a third thickness directly above a center point of the stairstep pattern of the first stack of magnetic layers, where the third thickness is greater than the first thickness, and where the third thickness is smaller than the second thickness.

In accordance with an embodiment, a semiconductor device includes a conductive pad over a substrate; a first polymer layer over the conductive pad; a first insulation layer over the first polymer layer; a plurality of first magnetic layers over the first insulation layer, where the plurality of first magnetic layers have a stairstep sidewall; a second polymer layer over the plurality of first magnetic layers, where a thickness of the second polymer layer above a center of a first step of the stairstep sidewall is different from a thickness of the second polymer layer above a center of a second step of the stairstep sidewall; a conductive feature over the second polymer layer; a third polymer layer over the second polymer layer and around the conductive feature; a second insulation layer over the second polymer layer and the third polymer layer; and a second magnetic layer over the second insulation layer. In an embodiment, the plurality of first magnetic layers include cobalt zirconium tantalum (CoZrTa). In an embodiment, the second polymer layer includes a sloping top surface. In an embodiment, the second polymer layer has a first thickness in a range from 2 µm to 3.5 µm at an outermost edge of the plurality of first magnetic layers, where the first thickness is measured from a bottom surface of the second polymer layer to a top surface of the second polymer layer. In an embodiment, the second polymer layer has a second thickness in a range from 0.2 µm to 1.6 µm directly above a first sidewall of a topmost layer of the plurality of first magnetic layers. In an embodiment, the second polymer layer has a third thickness in a range from 0.4 µm to 1.0 µm directly above a first point on a top surface of the topmost layer of the plurality of first magnetic layers, where the first point is less than 10 µm away from the first sidewall of the topmost layer of the plurality of first magnetic layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a conductive pad over a substrate;
a first polymer layer over the conductive pad;
a first insulation layer over the first polymer layer;
a plurality of first magnetic layers over the first insulation layer, wherein the plurality of first magnetic layers have a stairstep sidewall;
a second polymer layer over the plurality of first magnetic layers, wherein a thickness of the second polymer layer above a center of a first step of the stairstep sidewall is different from a thickness of the second polymer layer above a center of a second step of the stairstep sidewall;
a conductive feature over the second polymer layer;
a third polymer layer over the second polymer layer and around the conductive feature;
a second insulation layer over the second polymer layer and the third polymer layer; and
a second magnetic layer over the second insulation layer.

2. The semiconductor device of claim 1, wherein the plurality of first magnetic layers comprise cobalt zirconium tantalum (CoZrTa).

3. The semiconductor device of claim 1, wherein the second polymer layer comprises a sloping top surface.

4. The semiconductor device of claim 1, wherein the second polymer layer has a first thickness in a range from 2 µm to 3.5 µm at an outermost edge of the plurality of first magnetic layers, wherein the first thickness is measured from a bottom surface of the second polymer layer to a top surface of the second polymer layer.

5. The semiconductor device of claim 4, wherein the second polymer layer has a second thickness in a range from 0.2 µm to 1.6 µm directly above a first sidewall of a topmost layer of the plurality of first magnetic layers.

6. The semiconductor device of claim 5, wherein the second polymer layer has a third thickness in a range from 0.4 µm to 1.0 µm directly above a first point on a top surface of the topmost layer of the plurality of first magnetic layers, wherein the first point is less than 10 µm away from the first sidewall of the topmost layer of the plurality of first magnetic layers.

7. A semiconductor device comprising:
a conductive pad over a substrate;
a first insulation layer over the conductive pad;
a plurality of first magnetic layers over the first insulation layer, wherein the plurality of first magnetic layers have a stairstep sidewall;
a first polymer layer over the plurality of first magnetic layers, wherein a thickness of the first polymer layer increases in a direction from a topmost step of the stairstep sidewall towards a bottommost step of the stairstep sidewall;
a first conductive feature and a second conductive feature over the first polymer layer;
a second polymer layer over the first polymer layer and around each of the first conductive feature and the second conductive feature;
a second insulation layer over the first polymer layer and the second polymer layer; and
a second magnetic layer over the second insulation layer.

8. The semiconductor device of claim 7, wherein the plurality of first magnetic layers comprise cobalt zirconium tantalum (CoZrTa).

9. The semiconductor device of claim 7, wherein the first polymer layer has a first thickness in a range from 2 µm to 3.5 µm at an outermost edge of the plurality of first magnetic layers, wherein the first thickness is measured from a bottom surface of the first polymer layer to a top surface of the first polymer layer.

10. The semiconductor device of claim 9, wherein the first polymer layer has a second thickness in a range from 0.2 µm to 1.6 µm directly above a first sidewall of a topmost layer of the plurality of first magnetic layers.

11. The semiconductor device of claim 8, wherein the first polymer layer comprises an organic material.

12. The semiconductor device of claim 8, wherein a first vertical height between a topmost surface of the first polymer layer and a bottommost point of all top surfaces of the first polymer layer is in a range from 1 µm to 20 µm.

13. The semiconductor device of claim 12, wherein a second vertical height between a topmost surface of the plurality of first magnetic layers and a bottommost surface of the plurality of first magnetic layers is greater than the first vertical height.

14. A semiconductor device comprising:
a conductive pad over an interconnect structure;
a first insulation layer over the conductive pad and the interconnect structure;
a plurality of first magnetic layers over the first insulation layer, wherein the plurality of first magnetic layers have a stairstep sidewall;
a first polymer layer over the plurality of first magnetic layers, wherein a first vertical height between a topmost surface of the first polymer layer and a bottommost point of all top surfaces of the first polymer layer is in a range from 1 µm to 20 µm;
a first conductive feature and a second conductive feature over the first polymer layer;
a second polymer layer over the first polymer layer and around each of the first conductive feature and the second conductive feature;
a second insulation layer over the first polymer layer and the second polymer layer; and
a second magnetic layer over the second insulation layer.

15. The semiconductor device of claim 14, wherein a second vertical height between a topmost surface of the plurality of first magnetic layers and a bottommost surface of the plurality of first magnetic layers is greater than the first vertical height.

16. The semiconductor device of claim 14, wherein a thickness of the first polymer layer increases in a direction from a topmost step of the stairstep sidewall towards a bottommost step of the stairstep sidewall.

17. The semiconductor device of claim 14, wherein the first polymer layer comprises an organic material.

18. The semiconductor device of claim 14, wherein the first polymer layer comprises a polyimide.

19. The semiconductor device of claim 14, wherein the plurality of first magnetic layers and the second magnetic layer comprise cobalt zirconium tantalum (CoZrTa).

20. The semiconductor device of claim 14, wherein the second insulation layer comprises silicon nitride or silicon oxynitride.
